(19) United States
(12) Patent Application Publication
(10) Pub. No.: US 2008/0194096 A1
(43) Pub. Date: Aug. 14, 2008

(54) METHOD OF MANUFACTURING SEMICONDUCTOR DEVICE

(75) Inventor: Yoshihisa MATSUBARA, Kawasaki (JP)

Correspondence Address: YOUNG & THOMPSON, 209 Madison Street, Suite 500, ALEXANDRIA, VA, 22314, US

(73) Assignee: NEC ELECTRONICS CORPORATION, KAWASAKI (JP)

(21) Appl. No.: 12/014,814

(22) Filed: Jan. 16, 2008

(30) Foreign Application Priority Data
Feb. 9, 2007 (JP) 2007-030232

(51) Int. Cl. H01L 21/4763

(52) U.S. Cl. 438/618; 257/E21.495

(57) ABSTRACT

A method of manufacturing a semiconductor device comprises: forming a copper interconnect in an insulating film overlying a substrate; and annealing the copper interconnect at a temperature of 300° C. or less. The copper interconnect has a minimum interconnect width of 0.1 μm or less and a maximum interconnect width of 1 μm or less.

This application is based on Japanese patent application NO. 2007-030232, the content of which is incorporated herein by reference.

### BACKGROUND

1. Technical Field

The present invention relates to a method of manufacturing a semiconductor device.

2. Related Art

During manufacture of a semiconductor device having copper interconnects, a hillock (i.e., an extrusion occurred above the surface of a metal film) can be formed on the copper interconnects. The hillock is caused by secondary growth of single crystal grains in the copper interconnect. Specifically, as shown in a cross-sectional view of FIG. 7, a large single crystal grain 101 is formed by the secondary growth. When the single crystal grain 101 rises, a hillock can occur above the surface of a copper interconnect 100. U.S. Pat. No. 6,500,754 discloses a technique of annealing a copper interconnect at 400° C. or higher thereby to suppress occurrence of the hillock. The annealing is performed before CMP (Chemical Mechanical Polishing) is performed on the copper interconnect.

In addition to the U.S. Pat. No. 6,500,754, Japanese Patent Application Publication No. 2001-7114 (and its corresponding U.S. Pat. No. 6,514,853) and PCT International Publication No. 01/099168 are prior art documents relevant to the present invention.

The present inventor has recognized the following: Increase in an annealing temperature enables suppression of the hillocks, while causing generation of voids. As described in U.S. Pat. No. 6,500,754, when the annealing temperature is set to 400° C. or higher, a number of the voids occur after the CMP is performed. Each void having a length of about 0.1 μm may occur. Therefore, in a semiconductor device having the minimum interconnect width of 0.1 μm or less, suppression of the voids is particularly strongly required because occurrence of the voids can cause a serious defect.

### SUMMARY

According to the present invention, there is provided a method of manufacturing a semiconductor device. The method comprises: forming a copper interconnect in an insulating film overlying a substrate; and annealing said copper interconnect at a temperature of 300° C. or less. The copper interconnect has a minimum interconnect width of 0.1 μm or less and a maximum interconnect width of 1 μm or less.

According to the present invention, the annealing temperature of the copper interconnect is 300° C. or less. With the temperature, the occurrence of the voids can be sufficiently prevented. Further, the maximum width of the copper interconnect is set to 1 μm or less. When the interconnect width is 1 μm or less, even in the case where the annealing temperature is low, the occurrence of the hillock can be prevented. Therefore, according to the present invention, both of the hillock and the voids can be suppressed.

According to the present invention, the method of manufacturing a semiconductor device that is capable of suppressing both the hillock and the voids is provided.

### BRIEF DESCRIPTION OF THE DRAWINGS

The above and other objects, advantages and features of the present invention will be more apparent from the following description of several preferred embodiments taken in conjunction with the accompanying drawings, in which:

FIGS. 1A to 1C illustrate process cross-sectional views of one embodiment of a method of manufacturing a semiconductor device according to the present invention;

FIGS. 2A to 2C illustrate process cross-sectional views of the embodiment of a method of manufacturing a semiconductor device according to the present invention;

FIGS. 3A to 3C illustrate process cross-sectional views of the embodiment of a method of manufacturing a semiconductor device according to the present invention;

FIG. 4 is a graph for explaining effects of the embodiment;

FIG. 5 is a cross-sectional view for explaining effects of the embodiment;

FIG. 6 is a graph for explaining effects of the embodiment; and

FIG. 7 is a cross-sectional view for explaining the principle of the occurrence of the hillocks.

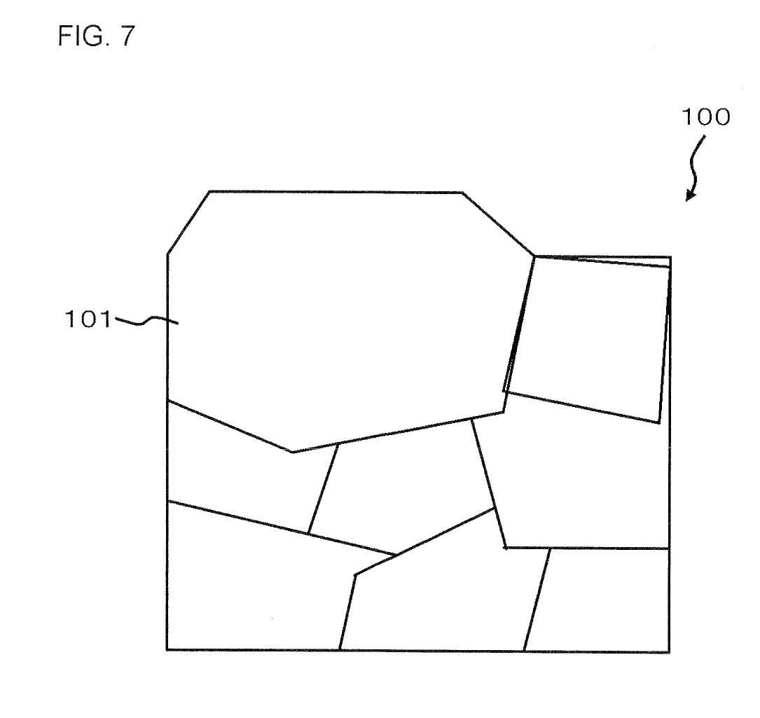

### DETAILED DESCRIPTION

The invention will now be described herein with reference to an illustrative embodiment. Those skilled in the art will recognize that many alternative embodiments can be accomplished using the teachings of the present invention and that the invention is not limited to the embodiments illustrated for explanatory purposed.

A preferred embodiment of a method of manufacturing a semiconductor device according to the present invention will be described in detail with reference to the drawings. It is understood, of course, that identical parts in the different figures are referred to by the same reference numeral.

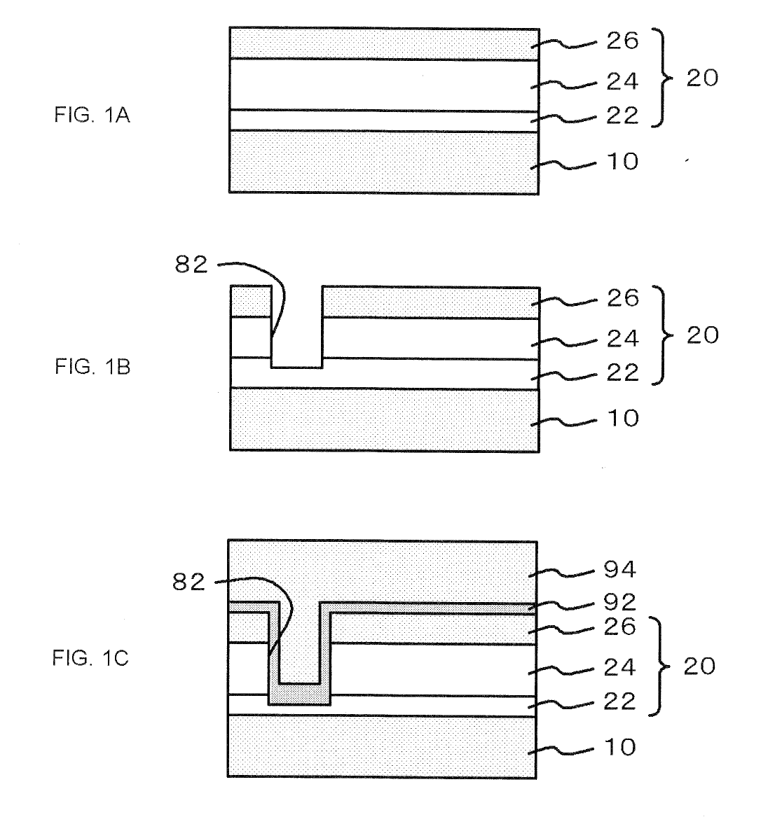

With reference to FIGS. 1A to 3C, an exemplary embodiment of a method of manufacturing a semiconductor device according to the present invention will be described. In short, the manufacturing method comprises the steps of: forming a copper interconnect in an insulating film overlying a semiconductor substrate; and annealing the copper interconnect at a temperature of 300° C. or less. In the copper interconnect formed in the insulating film, the copper interconnect has a minimum interconnect width of 0.1 μm or less and a maximum interconnect width of 1 μm or less.

More specifically, first, an insulating film 20 is formed over an insulating film 10 formed on a semiconductor substrate (not shown) such as a silicon substrate (FIG. 1A). In the embodiment, the insulating film 20 consists of stacked layers that are comprised of a SiCN film 22, a low-k (low-dielectric-constant) film 24, and a SiO₂ film 26. Thicknesses of the SiCN film 22, the low-k film 24, and the SiO₂ film 26 are, for example, 50 nm, 200 nm, and 100 nm, respectively. Subsequently, a trench 82 for a copper interconnect 50 is formed in the insulating film 20 (FIG. 1B). The copper interconnect 50 will be described later.

In the next step of the process, a barrier metal film 92 and a copper film 94 are formed to be embedded in the trench 82 (FIG. 1C). The copper film 94 will constitute a copper interconnect 50 which will be described later. The thicknesses of the barrier metal film 92 and the copper film 94 are, for example, 50 nm and 500 nm, respectively. In the embodiment, the copper film 94 is formed by plating such as electroplating. Immediately after the plating, the copper interconnect (i.e., the copper film 94) is annealed. The annealing temperature is 300° C. or less. The annealing temperature is, more preferably, 250° C. or more to 280° C. or less.

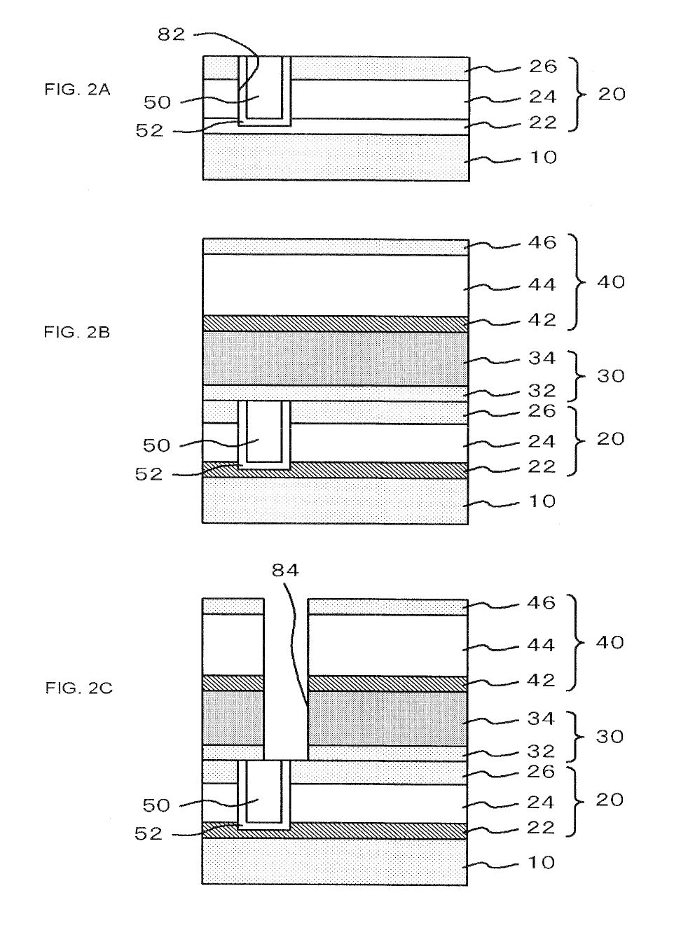

In the next step of the process, the barrier metal film 92 and the copper film 94 positioned on an area outside the trench 82 are removed by CMP. As a result, the copper interconnect 50 is formed through a barrier metal film 52 in the trench 82 (FIG. 2A). Subsequently, insulating films 30 and 40 are formed in this order over the insulating film 20 (FIG. 2B). The insulating films 30 and 40 can be formed by, for example, chemical vapor deposition (CVD) method. In this case, the annealing temperature is preferably equal to or higher than a treatment temperature achieved by the CVD method (i.e., a temperature in a chamber of a CVD system).

In this embodiment, the insulating film 30 consists of stacked layers that are comprised of a SiCN film 32 and a low-k film 34. The insulating film 40 consists of stacked layers that are comprised of a SiO₂ film 42, a low-k film 44, and a SiO₂ film 46. The thicknesses of the SiCN film 32, the low-k film 34, the SiO₂ film 42, the low-k film 44, and the SiO₂ film 46 are, for example, 50 nm, 200 nm, 100 nm, 200 nm, and 100 nm, respectively.

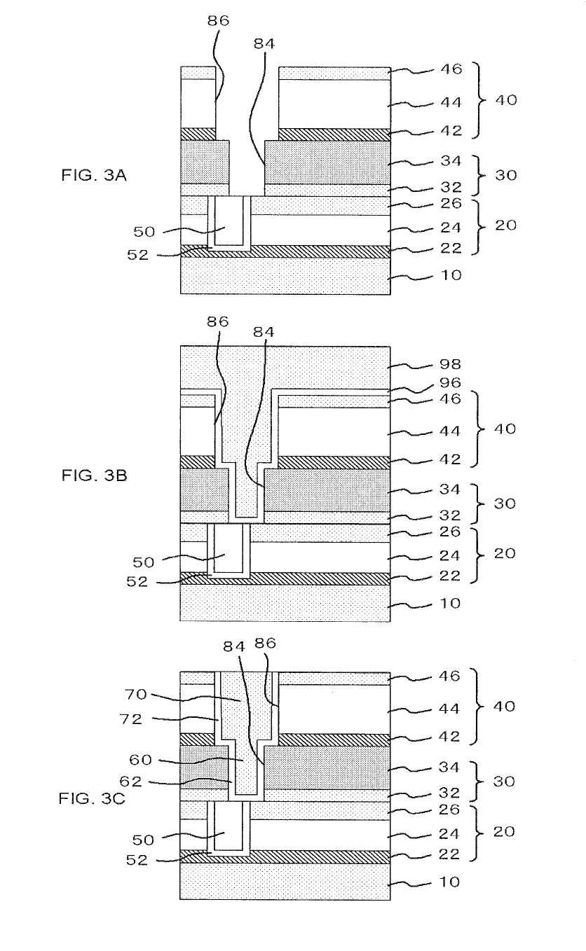

In the next step of the process, a via hole 84 is formed so as to penetrate the insulating films 30 and 40 (FIG. 2C). Subsequently, a trench 86 for a copper interconnect 70 is formed so as to penetrate the insulating film 40 (FIG. 3A). The copper interconnect 70 will be described later. The trench 86 is formed so as to be communicated with the via hole 84. Then, a barrier metal film 96 and a copper film 98 are formed in this order to be embedded in both the via hole 84 and the trench 86 (FIG. 3B). The copper film 98 will constitute a copper interconnect 70 which will be described later. Thicknesses of the barrier metal film 96 and the copper film 98 are, for example, 50 nm and 500 nm, respectively. The copper film 98 in this embodiment is formed by plating such as electroplating.

Immediately after the plating, the copper interconnect (i.e., the copper film 98) is annealed. The annealing temperature is the same as that in the above-described annealing of the copper film 94. Subsequently, the barrier metal film 96 and the copper film 98 positioned on an area outside both the via hole 84 and the trench 86 are removed by CMP. As a result, a via plug 60 is formed through a barrier metal film 62 in the via hole 84, and the copper interconnect 70 is formed through a barrier metal film 72 in the trench 86 (FIG. 3C). In this embodiment, the copper interconnects 50 and 70 correspond to an M1 interconnect and an M2 interconnect, respectively, where the M1 interconnect denotes an interconnect in the lowest layer of multilayered interconnects and the M2 interconnect denotes an interconnect in the second lowest layer.

The effects of the embodiment will be described. In the embodiment, the annealing temperature of the copper interconnect is 300° C. or less. With the temperature, occurrence of the voids can be sufficiently suppressed. Further, the maximum width of the copper interconnect is set to 1 μm or less. Namely, each of all the copper interconnects in the semiconductor device manufactured by the method has a width of 1 μm or less. When the interconnect width is 1 μm or less, even in the case where the annealing temperature is low, the occurrence of the hillock can be prevented. Therefore, in the embodiment, both of the hillock and the voids can be suppressed.

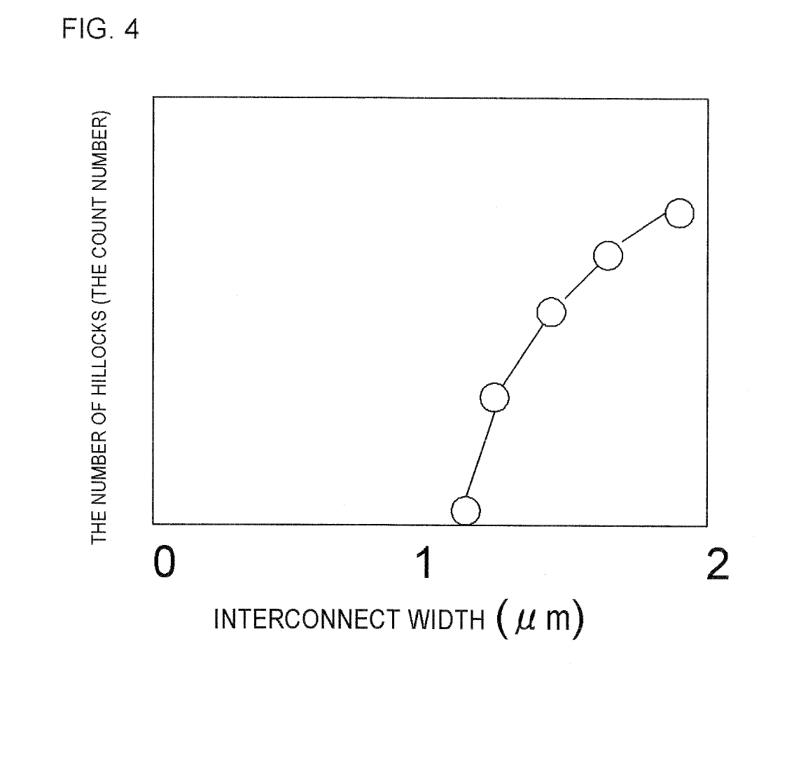

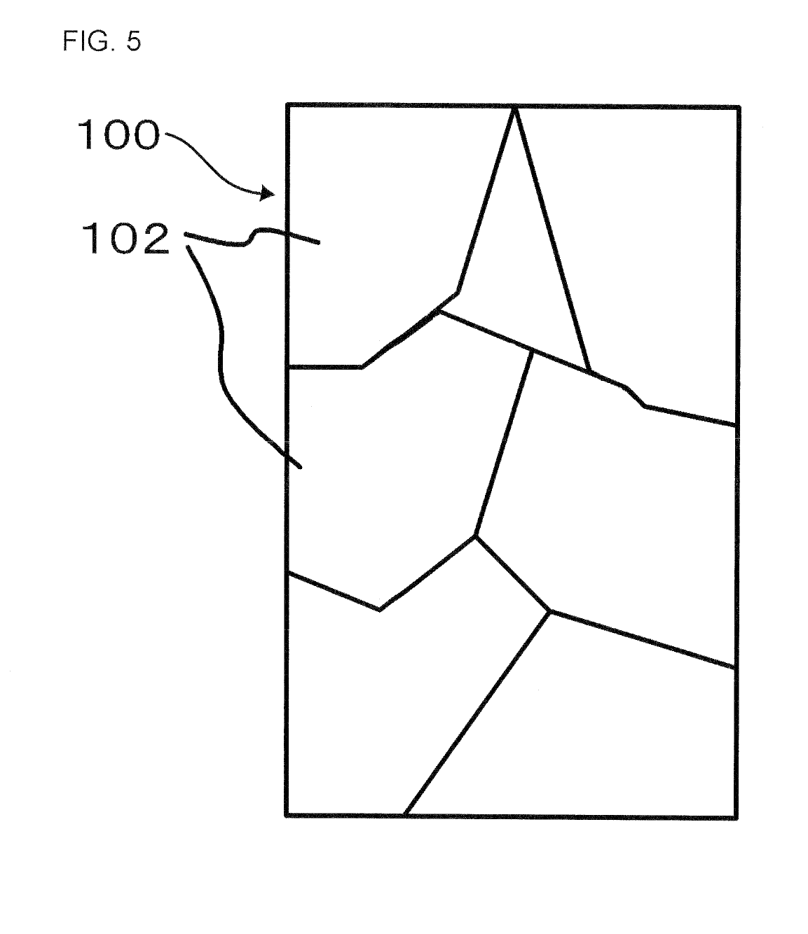

FIG. 4 is a graph representing the relationship between the number of hillocks and interconnect width, where the hillocks occurred in a copper interconnect. The hillocks were measured under the condition in which the annealing temperature is set to 250° C., and thicknesses of the SiCN film 22, the low-k film 24, and the SiO₂ film 26 are set to 50 nm, 200 nm, and 100 nm, respectively. As understood from the graph, the narrower the interconnect width is, the smaller the number of hillocks becomes. It is also recognized that, when the interconnect width is 1 μm or less, the number of the measured hillocks is zero. It is considered that, as shown in the cross-sectional view of FIG. 5, when the width of the copper interconnect 100 is narrow, secondary growth of a single crystal grain 102 in the copper interconnect 100 is suppressed.

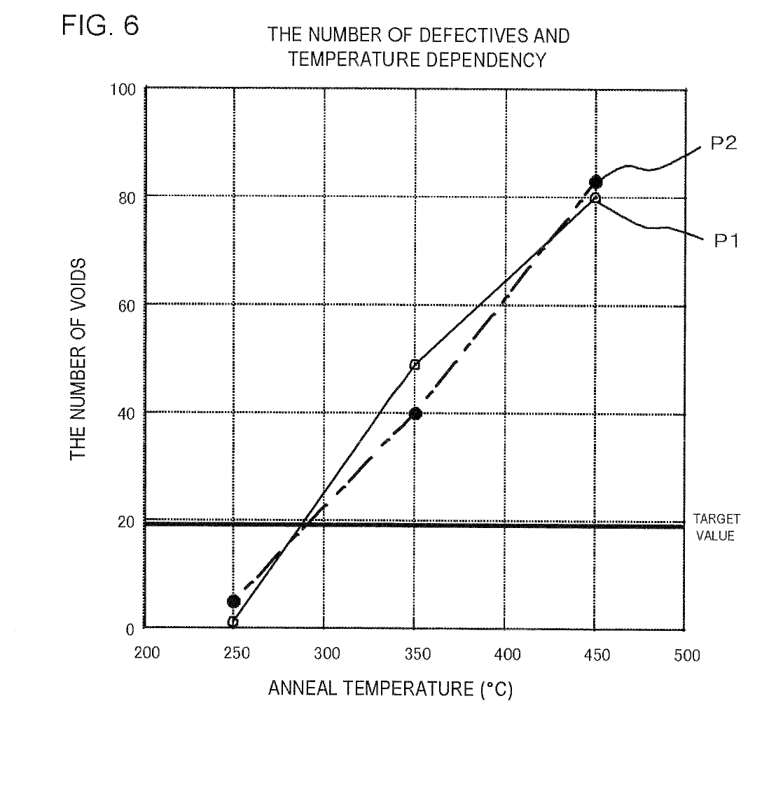

FIG. 6 is a graph representing the relationship between the number of voids and annealing temperature, where the voids occurred after a CMP process. The horizontal axis indicates the annealing temperature, that is, the heat treatment temperature (° C.) achieved immediately after plating. The annealing time is set to three minutes. The vertical axis indicates the number of voids that are measured. The number of voids has a value indicative of the number of defects caused by the voids when the defects were found in 100 places of a single wafer (through a visual check). Two wafers were test objects. Measurement results for one of the wafers are plotted as points P1 indicated by blank circles. Measurement results for the other of the wafers are plotted as points P2 indicated by solid circles.

As understood from the graph, when the annealing temperature is 300° C. or less, the number of voids occurred can be sufficiently suppressed. At around 300° C., although the number of voids exceeds a target value, the number of voids is within a permissible range. When the annealing temperature is 280° C. or less, the number of voids occurred can be suppressed to the target value or less.

If the annealing temperature is set to be equal to or higher than the treatment temperature achieved by the CVD method in the embodiment, peeling of the insulating film formed by the CVD method can be effectively prevented. Further, when the annealing temperature is set to 250° C. or higher, film formation by the CVD method can be performed at a relatively high temperature, thus enabling excellent quality of the film formed at a sufficiently high film formation rate.

In the foregoing specification, the invention has been described with reference to the specific exemplary embodiment thereof. It will, however, be evident that the present invention is not limited to the exemplary embodiment but can be variously modified. For example, a dual-damascene process for forming the copper interconnect has been described in the above embodiment. Nevertheless, the copper interconnect can be formed by a single-damascene process. Further, the copper interconnect can be connected to or cannot be connected to a pad when the copper interconnect is annealed. The pad in this case denotes a terminal portion that is electrically connected to a needle probe for test when an electrical test is performed.

It is apparent that the present invention is not limited to the above embodiment, and may be modified and changed without departing from the scope and spirit of the invention.

What is claimed is:

1. A method of manufacturing a semiconductor device, comprising:
forming a copper interconnect in an insulating film overlying a substrate, said copper interconnect having a minimum interconnect width of 0.1 μm or less and a maximum interconnect width of 1 μm or less; and
annealing said copper interconnect at a temperature of 300° C. or less.

2. The method of manufacturing a semiconductor device as set force in claim 1, wherein:
said forming a copper interconnect includes forming a copper film constituting said copper interconnect by plating; and
said annealing said copper interconnect is performed immediately after said plating.

3. The method of manufacturing a semiconductor device as set force in claim 1, further comprising, by chemical vapor deposition method, forming a second insulating film over said insulating film in which said copper interconnect is formed, after said annealing a copper interconnect,
wherein said annealing a copper interconnect is performed at a temperature equal to or higher than a treatment temperature obtained by said chemical vapor deposition method.

4. The method of manufacturing a semiconductor device as set force in claim 1, wherein said annealing said copper interconnect is performed at 250° C. or higher.

5. The method of manufacturing a semiconductor device as set force in claim 1, wherein said annealing said copper interconnect includes annealing said copper interconnect which is not connected to a pad.
